(19) United States
(12) Patent Application Publication
(10) Pub. No.: US 2024/0421175 A1
(43) Pub. Date: Dec. 19, 2024

(54) OPTICAL SEMICONDUCTOR ELEMENT

(71) Applicant: HAMAMATSU PHOTONICS K.K., Hamamatsu-shi, Shizuoka (JP)

(72) Inventors: Takahide YANAI, Hamamatsu-shi, Shizuoka (JP); Daisuke IIDA, Hamamatsu-shi, Shizuoka (JP); Asuka MISHIMA, Hamamatsu-shi, Shizuoka (JP)

(73) Assignee: HAMAMATSU PHOTONICS K.K., Hamamatsu-shi, Shizuoka (JP)

(21) Appl. No.: 18/701,366

(22) PCT Filed: Oct. 18, 2022
(86) PCT No.: PCT/JP2022/038741

§ 371 Date: Apr. 15, 2024

(30) Foreign Application Priority Data
Oct. 18, 2021 (JP) 2021-170201

(51) Int. Cl. H01L 27/146; H01L 27/15; H01L 33/20; H01L 33/40; H01L 33/62

(52) U.S. Cl. CPC H01L 27/14636; H01L 27/14649; H01L 27/156; H01L 33/20; H01L 33/40; H01L 33/62

(57) ABSTRACT

An optical semiconductor element includes: a substrate; and a plurality of cells formed on the substrate, the plurality of cells including a first cell, a second cell, and a third cell. A first electrode electrically connected to a first semiconductor layer of the first cell is arranged on the top surface of the first cell, and a second electrode electrically connected to a second semiconductor layer of the third cell is arranged on the top surface of the second cell. Each of the first electrode and the second electrode has a planned contact region with which solder comes into contact during electrical connection with an external member. When viewed from the thickness direction of the substrate, the area of the second electrode on the top surface of the second cell is smaller than the area of the first electrode on the top surface of the first cell.

### TECHNICAL FIELD

An aspect of the present disclosure relates to an optical semiconductor element.

### BACKGROUND ART

Patent Literature 1 describes a light emitting element that emits visible light or ultraviolet light. In the light emitting element, a plurality of light emitting cells each having an active layer are formed on the substrate, and two adjacent light emitting cells are electrically connected to each other by a bridge electrode.

### CITATION LIST

### Patent Literature

Patent Literature 1: Japanese Unexamined Patent Publication No. 2015-23293

### SUMMARY OF INVENTION

### Technical Problem

Light emitting elements such as that described above may be used by being electrically connected to an external member by solder, for example. In this case, it is required that the light emitting element can be stably connected to the external member by solder. In addition, the light emitting element is also required to improve light emission efficiency. These points also apply to light receiving elements. That is, the light receiving element is required to be stably connectable to the external member by solder and improve light reception efficiency.

An aspect of the present disclosure is to provide an optical semiconductor element that can be stably connected to an external member by solder and can improve light emission/reception efficiency.

### Solution to Problem

An optical semiconductor element according to an aspect of the present disclosure is [1] “an optical semiconductor element including: a substrate; and a plurality of cells formed on the substrate, the plurality of cells including a first cell, a second cell, and a third cell that are electrically connected. Each of the first cell and the third cell includes: an optical layer that is an active layer that generates light or an absorption layer that absorbs light; a first semiconductor layer arranged on a side opposite to the substrate with respect to the optical layer; and a second semiconductor layer having a different conductivity type from the first semiconductor layer and arranged on a side of the substrate with respect to the optical layer. The second cell includes at least a third semiconductor layer arranged on the substrate. A first electrode electrically connected to the first semiconductor layer of the first cell is arranged on a top surface of the first cell. A second electrode electrically connected to the second semiconductor layer of the third cell is arranged on a top surface of the second cell. Each of the first electrode and the second electrode includes a planned contact region with which solder comes into contact during electrical connection with an external member. When viewed from a thickness direction of the substrate, an area of the second electrode on the top surface of the second cell is smaller than an area of the first electrode on the top surface of the first cell”.

An optical semiconductor element according to an aspect of the present disclosure is [2] “an optical semiconductor element including: a substrate having a light transmissivity; and a plurality of cells formed on the substrate, the plurality of cells including a first cell and a second cell that are electrically connected. Each of the first cell and the second cell includes: an optical layer that is an active layer that generates light or an absorption layer that absorbs light; a first semiconductor layer arranged on a side opposite to the substrate with respect to the optical layer; and a second semiconductor layer having a different conductivity type from the first semiconductor layer and arranged on a side of the substrate with respect to the optical layer. Light generated in the optical layer is emitted through the substrate when the optical layer is the active layer, and light incident through the substrate is absorbed by the optical layer when the optical layer is the absorption layer. A first electrode electrically connected to the first semiconductor layer of the first cell is arranged on a top surface of the first cell. A second electrode electrically connected to the second semiconductor layer of the second cell is arranged on a top surface of the second cell. Each of the first electrode and the second electrode has a planned contact region with which solder comes into contact during electrical connection with an external member. When viewed from a thickness direction of the substrate, an area of the second electrode on the top surface of the second cell is smaller than an area of the first electrode on the top surface of the first cell”.

In these optical semiconductor elements, when viewed from the thickness direction of the substrate, the area of the second electrode on the top surface of the second cell may be smaller than the area of the first electrode on the top surface of the first cell. By reducing the area of the second electrode, it is possible to suppress the occurrence of a situation (solder erosion) in which the solder diffuses into the second electrode. That is, if the second electrode is electrically connected to the external member by solder, a phenomenon in which the solder diffuses into the second electrode may occur. However, by reducing the area of the second electrode, it is possible to suppress the diffusion of solder to the second electrode. In addition, by increasing the area of the first electrode, the current can be appropriately diffused from the first electrode to the semiconductor layer. As a result, it is possible to improve light emission/reception efficiency (light emission efficiency or light reception efficiency). In addition, since the areas of the first electrode and the second electrode are different, it is easy for the user to visually identify the first electrode and the second electrode when the first electrode and the second electrode are visible from the outside. Therefore, according to these optical semiconductor elements, stable connection with an external member using solder is possible, and the light emission/reception efficiency can be improved.

An optical semiconductor element according to an aspect of the present disclosure may be [3] “the optical semiconductor element according to [2], in which each of the first electrode and the second electrode is opaque to light generated or absorbed in the optical layer”. In this case, it is possible to suppress the emission and incidence of light from the side opposite to the substrate.

An optical semiconductor element according to an aspect of the present disclosure may be [4] “the optical semiconductor element according to any one of [1] to [3], in which the top surface of the second cell includes a non-forming portion in which the second electrode is not formed and the non-forming portion is located in a region on a side of the first electrode of the top surface of the second cell when viewed from the thickness direction of the substrate”. In this case, it is possible to suppress the occurrence of a short circuit between the first electrode and the second electrode.

An optical semiconductor element according to an aspect of the present disclosure may be [5] “the optical semiconductor element according to any one of [1] to [4], in which when viewed from the thickness direction of the substrate, a center of the planned contact region of the second electrode is located on a side opposite to the first electrode with respect to a center of the top surface of the second cell”. In this case, it is possible to suppress the occurrence of a short circuit between the first electrode and the second electrode.

An optical semiconductor element according to an aspect of the present disclosure may be [6] “the optical semiconductor element according to [1], in which the plurality of cells further include a fourth cell including the optical layer, the first semiconductor layer, and the second semiconductor layer, the second electrode is electrically connected to the second semiconductor layer of the third cell through a first wiring layer, the first semiconductor layer of the third cell is electrically connected to the second semiconductor layer of the fourth cell through a second wiring layer, and a width of a portion between the second cell and the third cell in the first wiring layer is larger than a width of a portion between the third cell and the fourth cell in the second wiring layer”. The solder may diffuse into the first wiring layer through the second electrode. However, since the width of the first wiring layer is large, it is possible to suppress the occurrence of wire breakage and the like in the first wiring layer even if the solder diffuses into the first wiring layer to reduce the strength of the first wiring layer.

An optical semiconductor element according to an aspect of the present disclosure may be [7] “the optical semiconductor element according to [1], in which the third semiconductor layer is arranged directly on the substrate and the second electrode is arranged on the third semiconductor layer”. In this case, it is possible to simplify the configuration of the second cell.

An optical semiconductor element according to an aspect of the present disclosure may be [8] “the optical semiconductor element according to [1], in which the second cell includes the optical layer, the third semiconductor layer arranged on the side opposite to the substrate with respect to the optical layer, a fourth semiconductor layer having a different conductivity type from the third semiconductor layer and arranged on the side of the substrate with respect to the optical layer, and an insulating layer arranged on the third semiconductor layer and the second electrode is arranged on the insulating layer”. In this case, since it is possible to reduce the difference in height between the second cell and the first and third cells, the optical semiconductor element can be easily mounted.

An optical semiconductor element according to an aspect of the present disclosure may be [9] “the optical semiconductor element according to [2], in which the plurality of cells further include an additional cell including the optical layer, the first semiconductor layer, and the second semiconductor layer and the first semiconductor layer of the second cell is electrically connected to the second semiconductor layer of the additional cell through a wiring layer”. In this case, it is possible to increase the light emission output.

An optical semiconductor element according to an aspect of the present disclosure may be [10] “the optical semiconductor element according to any one of [1] to [9], in which each of the first electrode and the second electrode includes a first layer and a second layer arranged on a side of the substrate with respect to the first layer”. In this case, it is possible to further suppress the diffusion of solder into the second electrode.

An optical semiconductor element according to an aspect of the present disclosure may be [11] “the optical semiconductor element according to [10], in which each of the first layer and the second layer includes a layer consisting of Ti, a layer consisting of Pt, and a layer consisting of Au in this order from the substrate side”. In this case, it is possible to further suppress the diffusion of solder into the second electrode.

An optical semiconductor element according to an aspect of the present disclosure may be [12] “the optical semiconductor element according to any one of [1] to [10], in which each of the first electrode and the second electrode is formed of a material containing at least Au”. When each of the first electrode and the second electrode is formed of a material containing Au, solder is likely to diffuse into the first electrode or the second electrode. However, according to this optical semiconductor element, even in such a case, the diffusion of solder into the second electrode can be suppressed.

An optical semiconductor element according to an aspect of the present disclosure may be [13] “the optical semiconductor element according to any one of [1] to [10], in which an insulating layer is formed on the first electrode and the second electrode except for the planned contact region”. In this case, it is possible to suppress the occurrence of a short circuit between the first electrode and the second electrode.

An optical semiconductor element according to an aspect of the present disclosure may be [14] “the optical semiconductor element according to any one of [1] to [13], in which each of the plurality of cells has a mesa structure including a side surface inclined with respect to the thickness direction of the substrate”. According to this optical semiconductor element, even when each cell has a mesa structure, stable connection with an external member using solder is possible.

An optical semiconductor element according to an aspect of the present disclosure is [15]×“an optical semiconductor element including: a substrate; and a plurality of cells formed on the substrate, the plurality of cells including a first cell and a second cell that are electrically connected. Each of the first cell and the second cell includes: an optical layer that is an active layer that generates light or an absorption layer that absorbs light; a first semiconductor layer arranged on a side opposite to the substrate with respect to the optical layer; and a second semiconductor layer having a different conductivity type from the first semiconductor layer and arranged on a side of the substrate with respect to the optical layer. A first electrode electrically connected to the first semiconductor layer of the first cell is arranged on a top surface of the first cell. A second electrode electrically connected to the second semiconductor layer of the second cell is arranged on the substrate. Each of the first electrode and the second electrode has a planned contact region with which solder comes into contact during electrical connection with an external member. When viewed from a thickness direction of the substrate, an area of the second electrode is smaller than an area of the first electrode on the top surface of the first cell”. With this optical semiconductor element as well, for the reasons mentioned above, stable connection with an external member using solder is possible, and the light emission/reception efficiency can be improved.

An optical semiconductor element according to an aspect of the present disclosure may be [16] “the optical semiconductor element according to [15], in which the plurality of cells adjacent to each other are spaced apart from each other by a groove formed in the substrate and an arrangement region on the substrate where the second electrode is arranged and the plurality of cells adjacent to the arrangement region are spaced apart from each other by a groove portion formed in the substrate”. In this case, the plurality of adjacent cells can be spatially separated from each other by the groove portion, and the arrangement region where the second electrode is arranged can be spatially separated from the plurality of cells adjacent to the arrangement region by the groove portion.

An optical semiconductor element according to an aspect of the present disclosure may be [17] “the optical semiconductor element according to [16], in which the arrangement region includes a non-forming portion in which the second electrode is not formed and the non-forming portion is located in a region on a side of the first electrode in the arrangement region when viewed from the thickness direction of the substrate”. In this case, it is possible to suppress the occurrence of a short circuit between the first electrode and the second electrode.

An optical semiconductor element according to an aspect of the present disclosure may be [18] “the optical semiconductor element according to [16] or [17], in which when viewed from the thickness direction of the substrate, a center of the planned contact region of the second electrode is located on a side opposite to the first electrode with respect to a center of the arrangement region”. In this case, it is possible to suppress the occurrence of a short circuit between the first electrode and the second electrode.

An optical semiconductor element according to an aspect of the present disclosure may be [19] “the optical semiconductor element according to any one of [16] to [18], in which the plurality of cells further include a third cell including the optical layer, the first semiconductor layer, and the second semiconductor layer, the second electrode is electrically connected to the second semiconductor layer of the second cell through a first wiring layer, the first semiconductor layer of the second cell is electrically connected to the second semiconductor layer of the third cell through a second wiring layer, and a width of a portion between the second electrode and the second cell in the first wiring layer is larger than a width of a portion between the second cell and the third cell in the second wiring layer”. The solder may diffuse into the first wiring layer through the second electrode. However, since the width of the first wiring layer is large, it is possible to suppress the occurrence of wire breakage and the like in the first wiring layer even if the solder diffuses into the first wiring layer to reduce the strength of the first wiring layer.

### Advantageous Effects of Invention

According to an aspect of the present disclosure, it is possible to provide an optical semiconductor element that can be stably connected to an external member by solder and can improve light emission/reception efficiency.

### BRIEF DESCRIPTION OF DRAWINGS

FIG. 1 is a plan view of an optical semiconductor element according to an embodiment.

FIG. 2 is a partially enlarged view of FIG. 1.

FIG. 3 is a partially enlarged view of FIG. 1.

FIG. 4 is a cross-sectional view taken along the line IV-IV of FIG. 1.

FIG. 5 is a diagram for explaining the cross-sectional structure of the optical semiconductor element.

FIG. 6 is a cross-sectional view showing a state in which an optical semiconductor element is mounted.

FIG. 7 is a plan view of an optical semiconductor element of a first modification example.

FIG. 8 is a cross-sectional view of an optical semiconductor element of a second modification example.

### DESCRIPTION OF EMBODIMENTS

Hereinafter, an embodiment of the present disclosure will be described in detail with reference to the diagrams. In the following description, the same or equivalent elements are denoted by the same reference numerals, and repeated description thereof will be omitted.

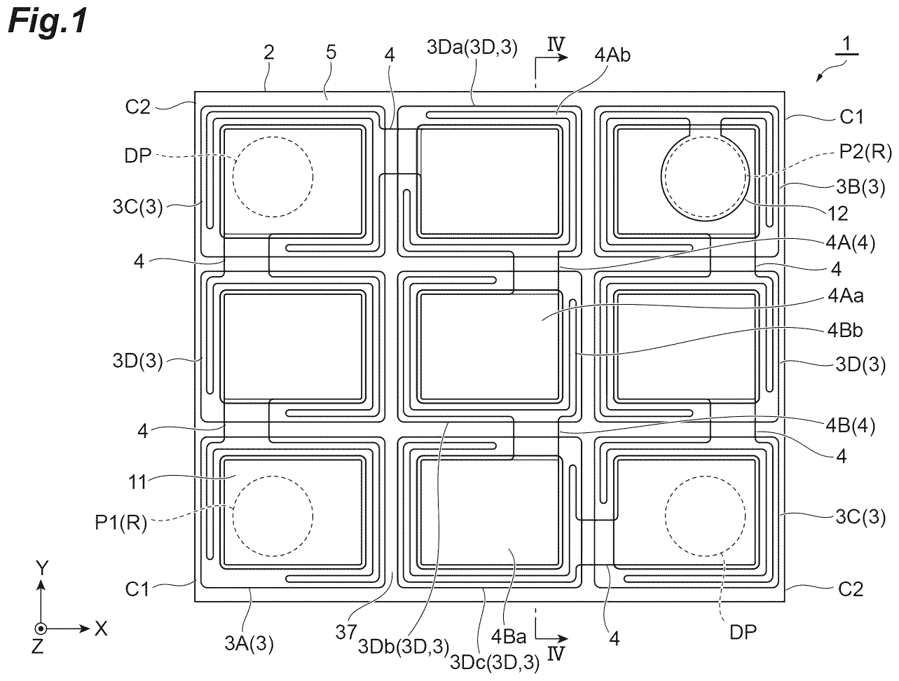

As shown in FIGS. 1 to 5, an optical semiconductor element 1 includes a substrate 2 and a plurality of (nine in this example) cells 3 formed on the substrate 2. Each cell 3 has an optical layer 31, a first semiconductor layer 32, and a second semiconductor layer 33. The optical semiconductor element 1 is a light emitting element or a light receiving element. In this example, the optical semiconductor element 1 is configured as a light emitting diode (LED), and the light generated in the optical layer 31 is emitted through the substrate 2.

The substrate 2 is a semiconductor having a light transmissivity, and is formed in a rectangular plate shape by, for example, GaAs or semi-insulating GaAs. The substrate 2 has a main surface 2a. Hereinafter, the thickness direction of the substrate 2 (direction perpendicular to the main surface 2a), the length direction of the substrate 2 (direction perpendicular to the Z direction), and the width direction of the substrate 2 (direction perpendicular to the Z direction and the X direction) will be described as a Z direction, an X direction, and a Y direction, respectively. The length of the substrate 2 (maximum length of the optical semiconductor element 1) in the X direction is, for example, 2 mm or less.

The plurality of cells 3 include a first termination cell 3A (first cell), a second termination cell 3B (second cell), a pair of dummy pad cells 3C, and a plurality of (five in this case) cells 3D (third cell, fourth cell, additional cell) other than the first termination cell 3A, the second termination cell 3B, and the dummy pad cells 3C. The plurality of cells 3 are arranged in a grid pattern so that three cells are aligned along each of the X direction and the Y direction. When viewed from the Z direction, the first termination cell 3A and the second termination cell 3B are arranged at two corners C1 located diagonally on the substrate 2, and the pair of dummy pad cells 3C are arranged at the remaining two corners C2 located diagonally on the substrate 2. In the optical semiconductor element 1, a plurality of cells 3 are electrically connected in series (in multiple stages) through a wiring layer 4 described later, and light is emitted from each cell 3. That is, each cell 3 is configured as a light emitting cell capable of emitting light. Each cell 3 has at least one semiconductor layer separated from the semiconductor layer of the adjacent cell 3.

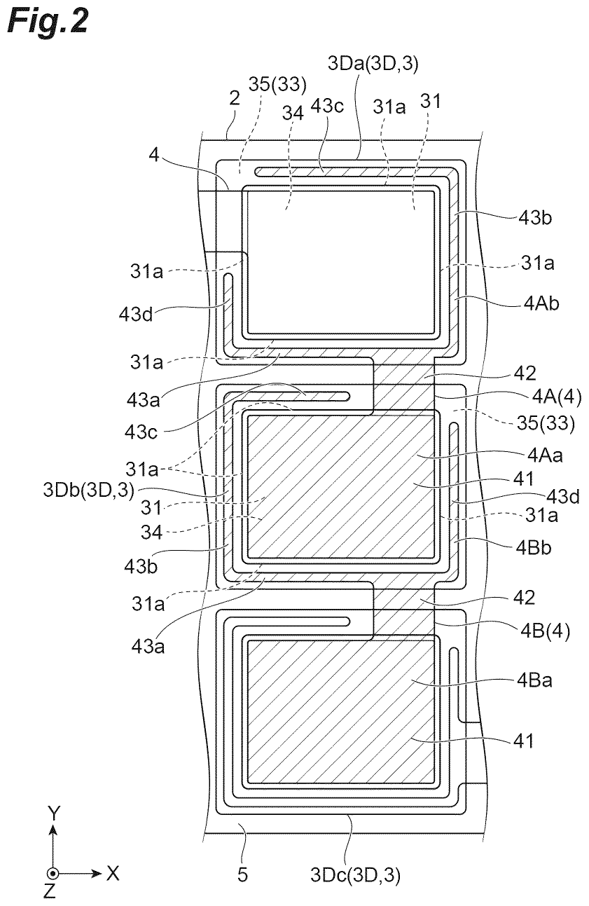

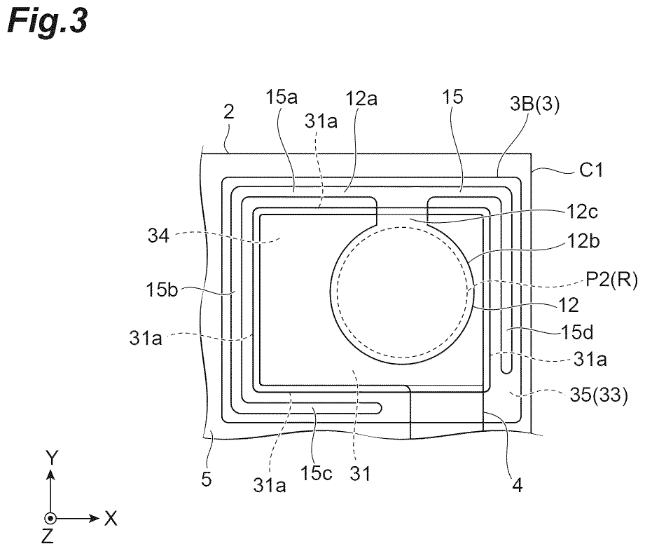

First, the configuration of the cell 3D will be described below. As described above, the cell 3D has the optical layer 31, the first semiconductor layer 32, and the second semiconductor layer 33. The second semiconductor layer 33, the optical layer 31, and the first semiconductor layer 32 are stacked in this order on the main surface 2a of the substrate 2. That is, the first semiconductor layer 32 is arranged on a side opposite to the substrate 2 (upper side in FIGS. 2 and 3) with respect to the optical layer 31, and the second semiconductor layer 33 is arranged on a side of the substrate 2 (lower side in FIGS. 2 and 3) with respect to the optical layer 31. The length of the cell 3D in the X direction (maximum length of the cell 3D) is, for example, 300 μm or less.

In this example, the optical layer 31 is an active layer that generates light, and is configured to generate light having a central wavelength of 3 μm or more and 10 μm or less. The optical layer 31 has, for example, a multiple quantum well structure in which a barrier layer formed of AlInAs and a well layer formed of InAsSb are alternately stacked. The optical layer 31 is formed in a rectangular shape when viewed from the Z direction, and has four straight side portions 31a. In this example, the optical layer 31 is formed in a rectangular shape having a long side along the X direction when viewed from the Z direction. The optical layer 31 may be formed in a square shape. In this example, the corners of the optical layer 31 and the cell 3D are sharp, but the corners of the optical layer 31 and the cell 3D may be rounded to have an R shape.

The first semiconductor layer 32 is a semiconductor layer of a first conductivity type (for example, p-type). For example, the first semiconductor layer 32 is formed by stacking a barrier layer, a buffer layer, and a contact layer on the optical layer 31 in this order. The second semiconductor layer 33 is a semiconductor layer of a second conductivity type (for example, n-type). For example, the second semiconductor layer 33 is formed by stacking a buffer layer, a contact layer, a current diffusion layer, and a barrier layer on the main surface 2a of the substrate 2 in this order. That is, the second semiconductor layer 33 has a different conductivity type from the first semiconductor layer 32. The material of each layer included in the first semiconductor layer 32 and the second semiconductor layer 33 can be appropriately selected depending on the material of the optical layer 31. As an example, the barrier layer of the first semiconductor layer 32 is formed of Al_{0.20}InAs, the buffer layer is formed of Al_{0.05}InAs, and the contact layer is formed of InAs. As an example, the buffer layer of the second semiconductor layer 33 includes three layers of GaAs, GaSb, and InAs, the contact layer and the current diffusion layer are formed of Al_{0.05}InAs, and the barrier layer is formed of Al_{0.20}InAs.

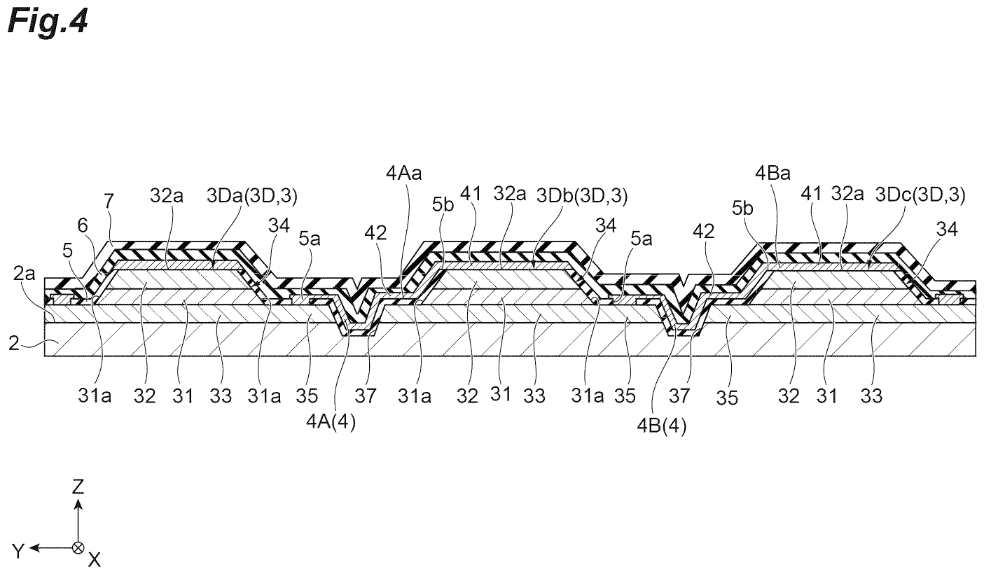

The optical layer 31 and the first semiconductor layer 32 form a mesa portion 34 formed on the second semiconductor layer 33. That is, the cell 3D has a mesa structure (pedestal structure). The mesa portion 34 is formed, for example, in a trapezoidal shape in a cross section (FIG. 4) perpendicular to the main surface 2a of the substrate 2 so as to protrude from the second semiconductor layer 33 to the side opposite to the substrate 2. Thus, the cell 3D in this example has a mesa structure including side surfaces inclined with respect to the Z direction. The mesa portion 34 is formed, for example, by stacking the optical layer 31, the first semiconductor layer 32, and the second semiconductor layer 33 on the substrate 2 and then removing parts of the substrate 2, the optical layer 31, the first semiconductor layer 32, and the second semiconductor layer 33 by etching. After forming the mesa portion 34, a groove portion 37 described later is formed.

The second semiconductor layer 33 has an outer portion 35 located outside the mesa portion 34. Here, the “outside” means the side away from the center of the mesa portion 34 in the direction perpendicular to the Z direction. The outer portion 35 is formed, for example, in a rectangular ring shape so as to surround the entire circumference of the mesa portion 34 when viewed from the Z direction.

FIGS. 2 and 4 show three cells 3D that are arranged in the Y direction so as to be electrically connected in series. Hereinafter, as shown in FIGS. 2 and 4, the three cells 3D will be described as a first cell 3Da, a second cell 3Db, and a third cell 3Dc, respectively.

The second semiconductor layer 33 of the first cell 3Da and the second semiconductor layer 33 of the second cell 3 Db are separated by a groove portion 37 so as to be electrically separated from each other. Similarly, the second semiconductor layer 33 of the second cell 3 Db and the second semiconductor layer 33 of the third cell 3Dc are separated from each other by the groove portion 37 so as to be electrically separated. As described above, in the optical semiconductor element 1, the second semiconductor layers 33 of the adjacent cells 3 are separated from each other by the groove portion 37 so as to be electrically separated. The groove portion 37 is formed in the second semiconductor layer 33, and extends, for example, in a grid pattern so as to pass between the adjacent cells 3 when viewed from the Z direction. In this example, the groove portion 37 is formed so as to reach the inside of the substrate 2 in the Z direction. However, the groove portion 37 only needs to electrically separate the second semiconductor layers 33 of the adjacent cells 3 from each other, and the groove portion 37 does not have to be formed so as to reach the inside of the substrate 2 in the Z direction.

The first cell 3Da and the second cell 3 Db are electrically connected to each other by a first wiring layer 4A (wiring layer 4) (wiring portion). Similarly, the second cell 3 Db and the third cell 3Dc are electrically connected to each other by a second wiring layer 4B (wiring layer 4) (wiring portion). As described above, in the optical semiconductor element 1, the wiring layer 4 realizes the electrical connection between the cells 3. The wiring layer 4 is formed, for example, by stacking a first layer formed of Ti, a second layer formed of Pt, and a third layer formed of Au, in this order from the substrate 2 side by vapor deposition. Hereinafter, the first wiring layer 4A and the second wiring layer 4B will be described, but the other wiring layers 4 (wiring portions) are similarly configured.

The first wiring layer 4A is formed on the first cell 3Da and the second cell 3 Db with a first insulating layer 5 interposed therebetween. That is, the first insulating layer 5 is formed over the first cell 3Da and the second cell 3 Db, and the first wiring layer 4A is formed on the first insulating layer 5. The first insulating layer 5 is formed of, for example, Al₂O₃, and is formed over the adjacent cells 3 and the inner surface of the groove portion 37 between the adjacent cells 3. A second insulating layer 6 is formed on the first insulating layer 5 and the first wiring layer 4A, and a third insulating layer 7 is formed on the second insulating layer 6. The second insulating layer 6 and the third insulating layer 7 are formed of, for example, Al₂O₃, and are formed over the entire surface of the substrate 2. The first insulating layer 5, the second insulating layer 6, and the third insulating layer 7 configured in this manner are transparent. In this example, a first electrode 11 and a second electrode 12, which will be described later, are visible from the outside through the second insulating layer 6 and the third insulating layer 7.

The first wiring layer 4A has a first connection portion 4Aa and a first extending portion 4Ab. The first connection portion 4Aa is electrically connected to the second semiconductor layer 33 of the first cell 3Da and the first semiconductor layer 32 of the second cell 3 Db. More specifically, the first connection portion 4Aa is in contact with the outer portion 35 of the second semiconductor layer 33 of the first cell 3Da through an opening 5a, and is in contact with a surface 32a of the first semiconductor layer 32 of the second cell 3 Db through an opening 5b. The openings 5a and 5b are openings formed in the first insulating layer 5. The surface 32a is a surface of the first semiconductor layer 32 on a side opposite to the optical layer 31, and forms a top surface of the mesa portion 34. The first connection portion 4Aa has a rectangular first portion 41 arranged on the surface 32a of the first semiconductor layer 32 of the second cell 3 Db and a rectangular second portion 42 extending from the first portion 41 to reach the outer portion 35 of the second semiconductor layer 33 of the first cell 3Da. The first portion 41 is arranged on the approximately entire surface 32a. The width of the second portion 42 in the X direction is smaller than the width of the first portion 41 in the X direction.

As shown in FIG. 2, when viewed from the Z direction, the first extending portion 4Ab extends from the second portion 42 of the first connection portion 4Aa so as to surround the four side portions 31a of the optical layer 31 of the first cell 3Da. The first extending portion 4Ab is in contact with the outer portion 35 of the second semiconductor layer 33 of the first cell 3Da through the opening 5a. In FIGS. 1 to 3, for convenience of explanation, a state in which the first insulating layer 5, the second insulating layer 6, and the third insulating layer 7 are omitted and the wiring layer 4 is exposed is shown. In addition, in FIG. 2, the first wiring layer 4A and the second wiring layer 4B are hatched for easy understanding.

In this example, the first extending portion 4Ab has four portions 43a, 43b, 43c, and 43d extending straight along the four side portions 31a, respectively. The portion 43a is connected to the second portion 42 of the first connection portion 4Aa. The first end of the portion 43b is connected to the first end of the portion 43a, and the portion 43b extends perpendicular to the portion 43a. The portion 43c is connected to the second end of the portion 43b, and extends perpendicular to the portion 43b and parallel to the portion 43a. The portion 43d is connected to the second end of the portion 43a, and extends perpendicular to the portion 43a and parallel to the portion 43b. In this example, the portion 43d is not connected to the portion 43c, and a gap is formed between the portions 43c and 43d when viewed from the Z direction. That is, the first extending portion 4Ab partially surrounds the four side portions 31a of the optical layer 31 of the first cell 3Da, and does not surround the entire circumference of the optical layer 31 of the first cell 3Da. The first extending portion 4Ab extends along at least a part of each of the four side portions 31a when viewed from the Z direction. As will be described later, a connection portion of another wiring layer 4 is arranged in the gap between the portions 43c and 43d.

The second wiring layer 4B is formed on the second cell 3 Db and the third cell 3Dc with the first insulating layer 5 interposed therebetween. The second wiring layer 4B has a second connection portion 4Ba and a second extending portion 4Bb. The second connection portion 4Ba is electrically connected to the second semiconductor layer 33 of the second cell 3 Db and the first semiconductor layer 32 of the third cell 3Dc. More specifically, the second connection portion 4Ba is in contact with the outer portion 35 of the second semiconductor layer 33 of the second cell 3 Db through the opening 5a, and is in contact with the surface 32a of the first semiconductor layer 32 of the third cell 3Dc through the opening 5b. The second connection portion 4Ba has a rectangular first portion 41 arranged on the surface 32a of the first semiconductor layer 32 of the third cell 3Dc and a rectangular second portion 42 extending from the first portion 41 to the outer portion 35 of the second semiconductor layer 33 of the second cell 3 Db.

As shown in FIG. 2, when viewed from the Z direction, the second extending portion 4Bb extends from the second portion 42 of the second connection portion 4Ba so as to surround the four side portions 31a of the optical layer 31 of the second cell 3 Db. The second extending portion 4Bb is in contact with the outer portion 35 of the second semiconductor layer 33 of the second cell 3 Db through the opening 5a. In this example, the second extending portion 4Bb has four portions 43a, 43b, 43c, and 43d extending straight along the four side portions 31a, respectively. The portion 43a is connected to the second portion 42 of the second connection portion 4Ba. The first end of the portion 43b is connected to the first end of the portion 43a, and the portion 43b extends perpendicular to the portion 43a. The portion 43c is connected to the second end of the portion 43b, and extends perpendicular to the portion 43b and parallel to the portion 43a. The portion 43d is connected to the second end of the portion 43a, and extends perpendicular to the portion 43a and parallel to the portion 43b. In this example, the portion 43d is not connected to the portion 43c, and a gap is formed between the portions 43c and 43d when viewed from the Z direction. That is, the second extending portion 4Bb partially surrounds the four side portions 31a of the optical layer 31 of the second cell 3 Db, and does not surround the entire circumference of the optical layer 31 of the second cell 3 Db. The second extending portion 4Bb extends along at least a part of each of the four side portions 31a when viewed from the Z direction. As will be described later, the first connection portion 4Aa of the first wiring layer 4A is arranged in the gap between the portions 43c and 43d.

In the present embodiment, the first connection portion 4Aa of the first wiring layer 4A does not overlap the second extending portion 4Bb of the second wiring layer 4B when viewed from the Z direction. The second portion 42 of the first connection portion 4Aa of the first wiring layer 4A is arranged so as to pass through the gap formed between the portions 43c and 43d of the second wiring layer 4B when viewed from the Z direction.

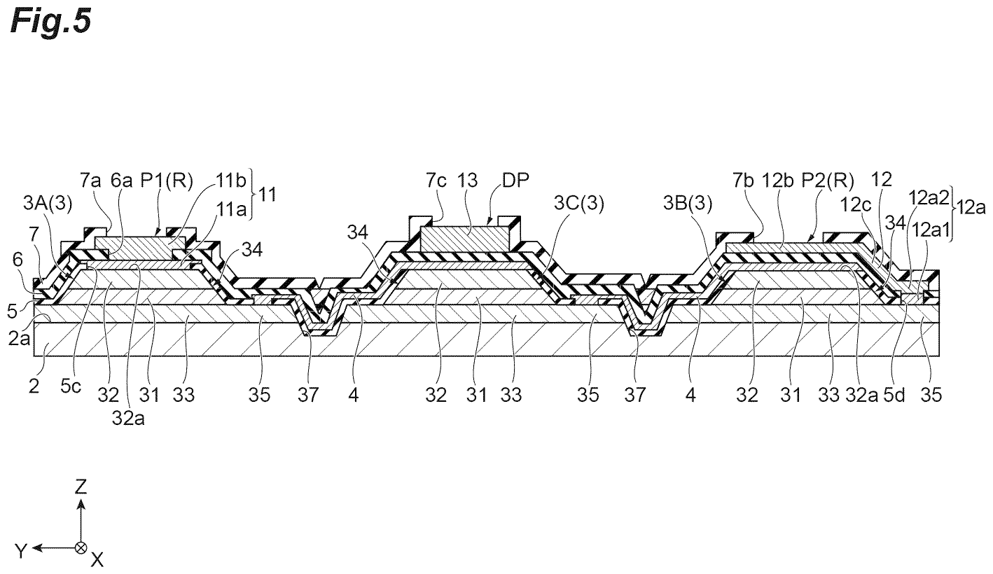

Subsequently, the configurations of the first termination cell 3A, the second termination cell 3B, and the dummy pad cell 3C will be described with reference to FIGS. 1, 3, and 5. The first termination cell 3A, the second termination cell 3B, and the dummy pad cell 3C have the same configuration as the cell 3D except for the matters described below. In FIG. 5, for convenience of explanation, the first termination cell 3A, the second termination cell 3B, and the dummy pad cell 3C are shown side by side virtually.

The first termination cell 3A is the cell 3 arranged at one end of the electrically series connection, and the second termination cell 3B is the cell 3 arranged at the other end of the electrically series connection. The first termination cell 3A and the second termination cell 3B are electrically connected to the adjacent cell 3 by the wiring layer 4.

A first electrode (anode) 11 is arranged on the top surface of the first termination cell 3A (top surface of the mesa portion 34). The first electrode 11 is electrically connected to the first semiconductor layer 32 of the first termination cell 3A. The first electrode 11 has a lower portion 11a (second layer) arranged on the surface 32a of the first semiconductor layer 32 and an upper portion 11b (first layer) arranged on the lower portion 11a. The lower portion 11a is in contact with the first semiconductor layer 32 of the first termination cell 3A through the opening 5c formed in the first insulating layer 5. The upper portion 11b is arranged in an opening 6a formed in the second insulating layer 6, and is exposed to the outside of the optical semiconductor element 1 from an opening 7a formed in the third insulating layer 7. The exposed portion in the upper portion 11b forms a first pad portion P1 for electrical connection with an external member 50 described later. The exposed portion is a planned contact region R with which solder comes into contact during electrical connection with the external member 50. The third insulating layer 7 is formed on the first electrode 11 except for the planned contact region R. In FIG. 1, the first pad portion P1 (planned contact region R) is shown by a broken line. In this example, when viewed from the Z direction, the first electrode 11 is formed in a rectangular shape, and the first pad portion P1 is formed in a circular shape. The first pad portion P1 is not limited to the circular shape, and may be formed in any shape such as a rectangular shape.

The lower portion 11a is formed by stacking a first layer consisting of Ti, a second layer consisting of Pt, and a third layer consisting of Au on the surface 32a in this order by vapor deposition. That is, the lower portion 11a has a three-layer structure similar to that of the wiring layer 4 described above. The upper portion 11b has a three-layer structure similar to that of the lower portion 11a and the wiring layer 4. Since the second layer formed of Pt is provided, it is possible to suppress the occurrence of a situation (solder erosion) in which the solder flows to the third layer of the lower portion 11a when the external member 50 is connected to the first pad portion P1 by soldering as described later. That is, if the second layer is not provided, a phenomenon called solder erosion may occur and the solder may flow to the third layer of the lower portion 11a. However, by providing the second layer consisting of Pt, it is possible to prevent the solder from flowing to the third layer of the lower portion 11a, so that it is possible to keep the flow of the solder to the third layer of the upper portion 11b. As a result, it is possible to satisfactorily control the shape of the solder. The lower portion 11a and the upper portion 11b (first electrode 11) configured as described above are opaque to light generated in the optical layer 31. In this example, the lower portion 11a and the upper portion 11b reflect light generated in the optical layer 31.

A second electrode (cathode) 12 is arranged on the top surface of the second termination cell 3B (top surface of the mesa portion 34). The second electrode 12 is electrically connected to the second semiconductor layer 33 of the second termination cell 3B. The second electrode 12 has a first portion 12a, a second portion 12b, and a connection portion 12c. The first portion 12a is electrically connected to the outer portion 35 of the second semiconductor layer 33 of the second termination cell 3B through an opening 5d formed in the first insulating layer 5. The second portion 12b is arranged on the second insulating layer 6 so as to overlap the top surface of the mesa portion 34 when viewed from the Z direction. The connection portion 12c is electrically connected to the first portion 12a and the second portion 12b. The second portion 12b is exposed to the outside of the optical semiconductor element 1 through an opening 7b formed in the third insulating layer 7. The exposed portion in the second portion 12b forms a second pad portion P2 for electrical connection with the external member 50. The exposed portion is a planned contact region R with which solder comes into contact during electrical connection with the external member 50. The third insulating layer 7 is formed on the second electrode 12 except for the planned contact region R. In FIG. 1, the second pad portion P2 (planned contact region R) is shown by a broken line. In this example, the second portion 12b and the second pad portion P2 are formed in a circular shape when viewed from the Z direction. As shown in FIG. 1, when viewed from the Z direction, the area of the second electrode 12 on the top surface of the second termination cell 3B (the area of the second portion 12b) is smaller than the area of the first electrode 11 on the top surface of the first termination cell 3A.

The first portion 12a includes a lower portion 12al (second layer) arranged on the outer portion 35 of the second semiconductor layer 33 of the second termination cell 3B and an upper portion 12a2 (first layer) arranged on the lower portion 12al. The lower portion 12al has a three-layer structure similar to that of the lower portion 11a of the first electrode 11. The upper portion 12a2, the second portion 12b, and the connection portion 12c have a three-layer structure similar to that of the lower portions 11a and 12al. The lower portion 12al and the upper portion 12a2 (second electrode 12) configured in this manner are opaque to light generated in the optical layer 31. In this example, the lower portion 12al and the upper portion 12a2 reflect light generated in the optical layer 31.

As shown in FIG. 3, the first portion 12a has an extending portion (third extending portion) 15. The extending portion 15 extends so as to surround the four side portions 31a of the optical layer 31 of the second termination cell 3B when viewed from the Z direction. In this example, the extending portion 15 has four portions 15a, 15b, 15c, and 15d extending straight along the four side portions 31a, respectively. The portion 15a is connected to the connection portion 12c. The first end of the portion 15b is connected to the first end of the portion 15a, and the portion 15b extends perpendicular to the portion 15a. The portion 15c is connected to the second end of the portion 15b, and extends perpendicular to the portion 15b and parallel to the portion 15a. The portion 15d is connected to the second end of the portion 15a, and extends perpendicular to the portion 15a and parallel to the portion 15b. In this example, the portion 15d is not connected to the portion 15c, and a gap is formed between the portions 15c and 15d when viewed from the Z direction. That is, the extending portion 15 partially surrounds the four side portions 31a of the optical layer 31 of the second termination cell 3B, and does not surround the entire circumference of the optical layer 31 of the second termination cell 3B. The extending portion 15 extends along at least a part of each of the four side portions 31a when viewed from the Z direction. A connection portion of the wiring layer 4 is arranged in the gap between the portions 15c and 15d. The extending portion 15 does not overlap the connection portion of the wiring layer 4 when viewed from the Z direction.

A dummy electrode 13 is arranged on the top surface of the dummy pad cell 3C (top surface of the mesa portion 34). The dummy electrode 13 is arranged on the second insulating layer 6 so as to overlap the first semiconductor layer 32 in the Z direction. The dummy electrode 13 has, for example, a layer structure similar to that of the lower portion 11a of the first electrode 11. The dummy electrode 13 is electrically separated (insulated) from the optical layer 31, the first semiconductor layer 32, and the second semiconductor layer 33 of the dummy pad cell 3C by the second insulating layer 6. The dummy electrode 13 is exposed to the outside of the optical semiconductor element 1 through an opening 7c formed in the third insulating layer 7. The exposed portion in the dummy electrode 13 forms a dummy pad portion DP. In FIG. 1, the dummy pad portion DP is shown by a broken line. The dummy pad portion DP is formed in a circular shape when viewed from the Z direction, but may be formed in any shape such as a rectangular shape.

The external member 50 is connected to the dummy pad portion DP by solder as in the case of the first pad portion P1 and the second pad portion P2. However, as described above, unlike the first pad portion P1 and the second pad portion P2, the dummy pad portion DP is electrically insulated from the optical layer 31, the first semiconductor layer 32, and the second semiconductor layer 33 of the dummy pad cell 3C.

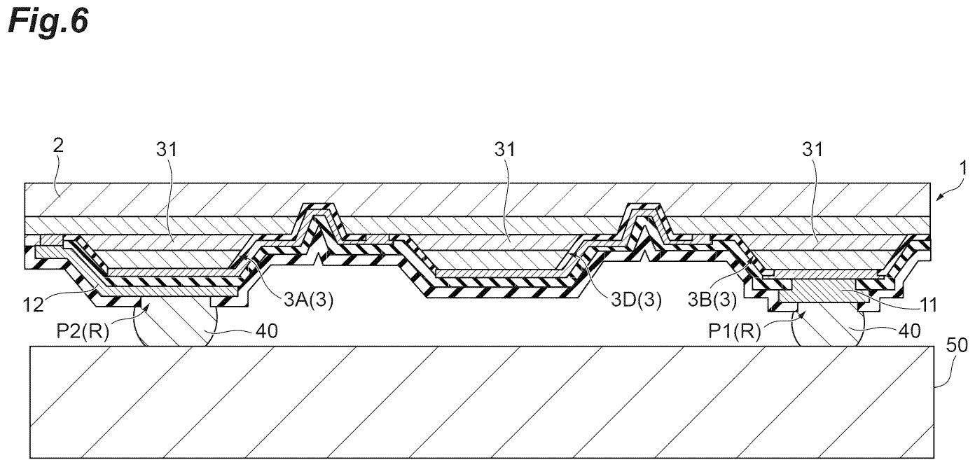

FIG. 6 is a cross-sectional view showing a state in which the optical semiconductor element 1 is mounted. FIG. 4 shows an example in which the optical semiconductor element 1 is electrically connected to the external member 50 by solder (bump, bonding material) 40. In this example, each of the first pad portion P1 (planned contact region R of the first electrode 11) and the second pad portion P2 (planned contact region R of the second electrode 12) is connected to the external member 50 by the solder 40. In addition, although not shown, the dummy pad portion DP is connected to the external member 50 by the solder 40. During operation of the optical semiconductor element 1, a voltage is applied between the first pad portion P1 (first electrode 11) and the second pad portion P2 (second electrode 12) through the external member 50. As a result, in each cell 3, carriers are injected into the optical layer 31 to generate light, and the generated light is emitted through the substrate 2. In addition, instead of the solder 40, an Au bump or an In bump may be used as a bonding material.

### Functions and Effects

The optical semiconductor element 1 includes the substrate 2 having a light transmissivity and a plurality of cells 3 formed on the substrate 2, the plurality of cells 3 including a first termination cell 3A (first cell) and a second termination cell 3B (second cell) electrically connected to each other. Each of the first termination cell 3A and the second termination cell 3B includes the optical layer 31 that is an active layer that generates light, the first semiconductor layer 32 arranged on a side opposite to the substrate 2 with respect to the optical layer 31, and the second semiconductor layer 33 having a different conductivity type from the first semiconductor layer 32 and arranged on a side of the substrate 2 with respect to the optical layer 31. Light generated in the optical layer 31 is emitted through the substrate 2. The first electrode 11 electrically connected to the first semiconductor layer 32 of the first termination cell 3A is arranged on the top surface of the first termination cell 3A. The second electrode 12 electrically connected to the second semiconductor layer 33 of the second termination cell 3B is arranged on the top surface of the second termination cell 3B. Each of the first electrode 11 and the second electrode 12 has the planned contact region R with which the solder 40 comes into contact during electrical connection with the external member 50. When viewed from the Z direction (thickness direction of the substrate 2), the area of the second electrode 12 on the top surface of the second termination cell 3B is smaller than the area of the first electrode 11 on the top surface of the first termination cell 3A.

In the optical semiconductor element 1, when viewed from the Z direction, the area of the second electrode 12 on the top surface of the second termination cell 3B is smaller than the area of the first electrode 11 on the top surface of the first termination cell 3A. By reducing the area of the second electrode 12, it is possible to suppress the occurrence of a situation (solder erosion) in which the solder 40 diffuses into the second electrode 12. That is, when the second electrode 12 is electrically connected to the external member 50 by the solder 40, a phenomenon in which the solder 40 diffuses into the second electrode 12 may occur. However, the diffusion of the solder 40 into the second electrode 12 can be suppressed by reducing the area of the second electrode 12. By suppressing the diffusion of the solder 40 into the second electrode 12, it is possible to suppress a reduction in the strength of the solder 40. In addition, it is possible to suppress a reduction in the height of the solder 40 due to diffusion into the second electrode 12. The second electrode 12 is electrically connected to the adjacent cell 3 through the wiring layer 4. Therefore, in the second electrode 12, the area where the solder 40 can diffuse is larger than in the first electrode 11 formed only on the top surface of the first termination cell 3A. For this reason, reducing the area of the second electrode 12 is effective in suppressing the diffusion of solder. In addition, by increasing the area of the first electrode 11, a current can be appropriately diffused from the first electrode 11 to the semiconductor layer (the first semiconductor layer 32 and the second semiconductor layer 33). As a result, it is possible to improve the light emission efficiency. In addition, since the areas of the first electrode 11 and the second electrode 12 are different, it is easy for the user to visually identify the first electrode 11 and the second electrode 12 when the first electrode 11 and the second electrode 12 are visible from the outside. In addition, the optical semiconductor element 1 includes a plurality of cells 3. By increasing the number of the plurality of cells 3, the area per cell 3 can be reduced, and as a result, the area of the second termination cell 3B can be reduced. If the area of the second termination cell 3B is small, the area of the second electrode 12 can be made small, and as a result, the area where the solder 40 can diffuse can be made small. In addition, when a plurality of cells 3 are formed on the substrate 2, the size (area) of the substrate 2 increases, and the force applied to the solder 40 increases. In this case, the diffusion of the solder 40 into the second electrode 12 tends to be a problem. In this regard, according to the optical semiconductor element 1, even when a plurality of cells 3 are formed on the substrate 2, stable connection with the external member 50 using the solder 40 is possible. As described above, according to the optical semiconductor element 1, stable connection with the external member 50 using the solder 40 is possible, and the light emission efficiency can be improved.

Each of the first electrode 11 and the second electrode 12 is opaque to light generated in the optical layer 31. Therefore, it is possible to suppress the emission of light from the side opposite to the substrate 2.

The first semiconductor layer 32 of the second termination cell 3B is electrically connected to the second semiconductor layer 33 of the cell 3D (additional cell) through the wiring layer 4. Therefore, it is possible to increase the light emission output.

Each of the first electrode 11 and the second electrode 12 includes a first layer (upper portion 11b, upper portion 12a2) and a second layer (lower portion 11a, lower portion 12a1) arranged on a side of the substrate 2 with respect to the first layer. Therefore, it is possible to further suppress the diffusion of the solder 40 into the second electrode 12.

Each of the first layer and the second layer includes a layer consisting of Ti, a layer consisting of Pt, and a layer consisting of Au in this order from the substrate 2 side. Therefore, it is possible to further suppress the diffusion of the solder 40 into the second electrode 12.

Each of the first electrode 11 and the second electrode 12 is formed of a material containing at least Au. When the first electrode 11 or the second electrode 12 is formed of a material containing Au, the solder 40 is likely to diffuse into the first electrode 11 or the second electrode 12. However, according to the optical semiconductor element 1, even in such a case, it is possible to suppress the diffusion of the solder 40 into the second electrode 12.

The third insulating layer 7 is formed on the first electrode 11 and the second electrode 12 except for the planned contact region R. Therefore, it is possible to suppress the occurrence of a short circuit between the first electrode 11 and the second electrode 12.

Each of the plurality of cells 3 has a mesa structure. According to the optical semiconductor element 1, even when each cell 3 has a mesa structure, stable connection with the external member 50 using the solder 40 is possible.

### Modification Examples

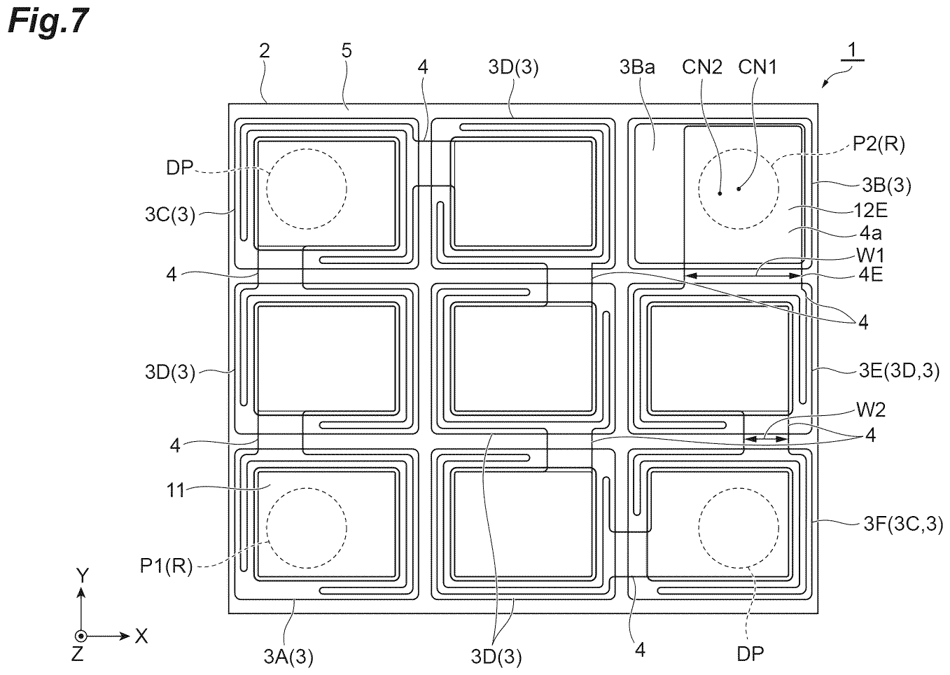

In a first modification example shown in FIG. 7, the second electrode 12 is not provided in the second termination cell 3B, and the second pad portion P2 is formed by a connection portion 4a of the wiring layer 4 exposed from the openings formed in the second insulating layer 6 and the third insulating layer 7. In FIG. 7, the second pad portion P2 is shown by a broken line. In the first modification example, the second termination cell 3B does not emit light. That is, the second termination cell 3B is configured as a non-light-emitting cell that does not emit light. In the first modification example, the connection portion 4a of the wiring layer 4 is formed on the first semiconductor layer 32 with the first insulating layer 5 interposed therebetween. That is, in the second termination cell 3B, the opening 5b is not formed in the first insulating layer 5, and the connection portion 4a of the wiring layer 4 is not in contact with the surface 32a of the first semiconductor layer 32.

In the first modification example, a portion of the wiring layer 4 arranged on the top surface of the second termination cell 3B can be regarded as forming the second electrode. Hereinafter, the portion of the wiring layer 4 arranged on the top surface of the second termination cell 3B will be referred to as a second electrode 12E, and a portion of the wiring layer 4 other than the portion will be referred to as a wiring layer 4E. That is, the second electrode 12E is arranged on the top surface of the second termination cell 3B (top surface of the mesa portion 34). The second electrode 12E is formed in a rectangular shape with long sides parallel to the Y direction. The second electrode 12E is electrically connected to the second semiconductor layer 33 of the adjacent cell 3D (third cell) through the wiring layer 4E (first wiring layer). Hereinafter, the cell 3D to which the second electrode 12E is electrically connected through the wiring layer 4E will be referred to as a cell 3E (third cell). The second termination cell 3B is adjacent to the cell 3E in the Y direction. The second electrode 12E is arranged on the first insulating layer 5 and is electrically insulated from the first semiconductor layer 32 of the second termination cell 3B, and is exposed through the openings formed in the second insulating layer 6 and the third insulating layer 7. The exposed portion of the second electrode 12E forms the second pad portion P2 for electrical connection with the external member 50. The exposed portion is the planned contact region R with which the solder 40 comes into contact during electrical connection with the external member 50. The second insulating layer 6 and the third insulating layer 7 are formed on the second electrode 12 except for the planned contact region R. In this example, the second pad portion P2 is formed in a circular shape. As shown in FIG. 7, when viewed from the Z direction, the area of the second electrode 12E on the top surface of the second termination cell 3B is smaller than the area of the first electrode 11 on the top surface of the first termination cell 3A. The second electrode 12E may be formed directly on the first semiconductor layer 32. For example, an opening may be formed in the first insulating layer 5, and the second electrode 12E may be in contact with the first semiconductor layer 32 through the opening.

As shown in FIG. 7, the top surface of the second termination cell 3B has a non-forming portion 3Ba in which the second electrode 12E is not formed. The non-forming portion 3Ba is an exposed portion of the top surface of the second termination cell 3B that is exposed from the second electrode 12E. In this example, the non-forming portion 3Ba is covered by the second insulating layer 6 and the third insulating layer 7. The non-forming portion 3Ba is located in a region of the top surface of the second termination cell 3B on the first electrode 11 side (lower left side in FIG. 7 in this example) when viewed from the Z direction. The non-forming portion 3Ba is located between the second electrode 12E and the first electrode 11 when viewed from the Z direction. In this example, the non-forming portion 3Ba is formed in a rectangular shape with long sides parallel to the Y direction, and is adjacent to the second electrode 12E in the X direction.

When viewed from the Z direction, the center CN1 of the planned contact region R of the second electrode 12E is located on a side (upper right side in FIG. 7 in this example) opposite to the first electrode 11 with respect to the center CN2 of the top surface of the second termination cell 3B. In this example, the center CN1 is located on the side opposite to the first electrode 11 with respect to the center CN2 in both the X direction (direction perpendicular to the Z direction) and the Y direction (perpendicular to the X and Z directions). However, the center CN1 may be located at the same position as the center CN2 in one of the X and Y directions.

The cell 3E (third cell) is electrically connected to the second semiconductor layer 33 of the adjacent cell 3 (dummy pad cell 3C, fourth cell) through the wiring layer 4 (second wiring layer). Hereinafter, the cell 3 to which the cell 3E is electrically connected through the wiring layer 4 will be referred to as a cell 3F (fourth cell). The cell 3E is adjacent to the cell 3F in the Y direction. As shown in FIG. 7, the width W1 of the wiring layer 4E that connects the second termination cell 3B and the cell 3E to each other is larger than the width W2 of the wiring layer 4 that connects the cell 3E and the cell 3F to each other. More specifically, the width W1 of a portion between the second termination cell 3B and the cell 3E in the wiring layer 4E is larger than the width W2 of a portion between the cell 3E and the cell 3F in the wiring layer 4. In this example, the width of the wiring layer 4 that connects the cells 3 other than the second termination cell 3B is the width W2 for all of the cells 3.

### Functions and Effects of First Modification Example

The optical semiconductor element 1 of the first modification example includes the substrate 2 and a plurality of cells 3 formed on the substrate 2, the plurality of cells 3 including the first termination cell 3A (first cell), the second termination cell 3B (second cell), and the cell 3E (third cell) that are electrically connected. Each of the first termination cell 3A and the cell 3E includes the optical layer 31 that is an active layer that generates light, the first semiconductor layer 32 arranged on a side opposite to the substrate 2 with respect to the optical layer 31, and the second semiconductor layer 33 having a different conductivity type from the first semiconductor layer 32 and arranged on a side of the substrate 2 with respect to the optical layer 31. The second termination cell 3B has at least a third semiconductor layer (for example, the first semiconductor layer 32 or the second semiconductor layer 33) arranged on the substrate 2. The first electrode 11 electrically connected to the first semiconductor layer 32 of the first termination cell 3A is arranged on the top surface of the first termination cell 3A. The second electrode 12E electrically connected to the second semiconductor layer 33 of the cell 3E is arranged on the top surface of the second termination cell 3B. Each of the first electrode 11 and the second electrode 12E has the planned contact region R with which the solder 40 comes into contact during electrical connection with the external member 50. When viewed from the Z direction (thickness direction of the substrate 2), the area of the second electrode 12E on the top surface of the second termination cell 3B is smaller than the area of the first electrode 11 on the top surface of the first termination cell 3A. With the optical semiconductor element 1 of the first modification example as well, for the reasons mentioned above, stable connection with the external member 50 using the solder 40 is possible and the light emission efficiency can be improved, as in the embodiment described above.

The top surface of the second termination cell 3B has the non-forming portion 3Ba in which the second electrode 12E is not formed, and the non-forming portion 3Ba is located in a region on the first electrode 11 side of the top surface of the second termination cell 3B when viewed from the Z direction. Therefore, it is possible to suppress the occurrence of a short circuit between the first electrode 11 and the second electrode 12E.

When viewed from the Z direction, the center CN1 of the planned contact region R of the second electrode 12E is located on the side opposite to the first electrode 11 with respect to the center CN2 of the top surface of the second termination cell 3B. Therefore, it is possible to suppress the occurrence of a short circuit between the first electrode 11 and the second electrode 12E.

The second electrode 12E is electrically connected to the second semiconductor layer 33 of the cell 3E (third cell) through the wiring layer 4E (first wiring layer), and the first semiconductor layer 32 of the cell 3E is electrically connected to the second semiconductor layer 33 of the cell 3F (fourth cell) through the wiring layer 4 (second wiring layer). The width W1 of a portion of the wiring layer 4E between the second termination cell 3B and the cell 3E is larger than the width W2 of a portion of the wiring layer 4 between the cell 3E and the cell 3F. The solder 40 may diffuse into the wiring layer 4E through the second electrode 12E. However, since the width W1 of the wiring layer 4E is large, it is possible to suppress the occurrence of wire breakage and the like in the wiring layer 4E even if the solder 40 diffuses into the wiring layer 4E to reduce the strength of the wiring layer 4E.

The second termination cell 3B includes the optical layer 31, the first semiconductor layer 32 (third semiconductor layer) arranged on a side opposite to the substrate 2 with respect to the optical layer 31, the second semiconductor layer 33 (fourth semiconductor layer) having a different conductivity type from the first semiconductor layer 32 and arranged on a side of the substrate 2 with respect to the optical layer 31, and the first insulating layer 5, the second insulating layer 6, and the third insulating layer 7 that are arranged on the first semiconductor layer 32; and the second electrode 12E is arranged on the first insulating layer 5. Therefore, since it is possible to reduce the difference in height between the second termination cell 3B and the first termination cell 3A and the cell 3E, the optical semiconductor element 1 can be easily mounted.

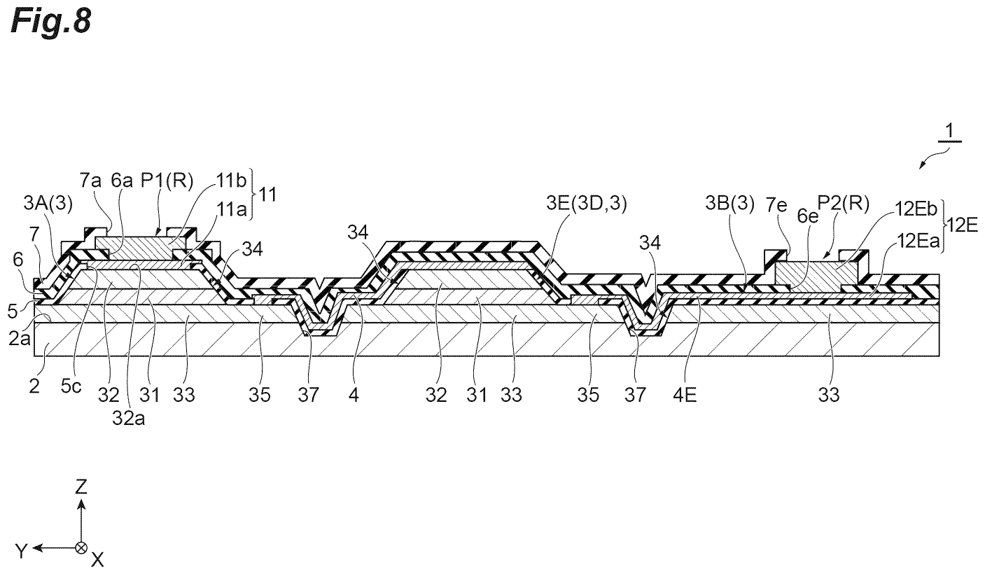

FIG. 8 is a cross-sectional view of an optical semiconductor element 1 of a second modification example. The optical semiconductor element 1 of the second modification example is configured in the same manner as the first modification example except for the matters described below. In FIG. 8, for convenience of explanation, the first termination cell 3A, the cell 3E, and the second termination cell 3B are shown side by side virtually.

In the second modification example, the second termination cell 3B does not include the optical layer 31 and the first semiconductor layer 32, but only includes the second semiconductor layer 33. The second semiconductor layer 33 is formed directly on the substrate 2. The second electrode 12E is formed on the second semiconductor layer 33. In this example, the second electrode 12E is formed on the second semiconductor layer 33 with the first insulating layer 5 interposed therebetween. That is, in the second termination cell 3B, no opening is formed in the first insulating layer 5, and the second electrode 12E is not in contact with the second semiconductor layer 33. The second semiconductor layer 33 forms the mesa portion 34 formed on the substrate 2. The second electrode 12 may be arranged directly on the second semiconductor layer 33. For example, an opening may be formed in the first insulating layer 5, and the second electrode 12 may be in contact with the second semiconductor layer 33 through the opening. The second termination cell 3B may include only the first semiconductor layer 32 instead of the second semiconductor layer 33.

In the second modification example, the second electrode 12E has a lower portion 12Ea (second layer) arranged on the second semiconductor layer 33 with the first insulating layer 5 interposed therebetween and an upper portion 12Eb (first layer) arranged on the lower portion 12Ea. The lower portion 12Ea is electrically insulated from the second semiconductor layer 33 by the first insulating layer 5. The upper portion 12Eb is arranged within an opening 6e formed in the second insulating layer 6, and is exposed to the outside of the optical semiconductor element 1 through an opening 7e formed in the third insulating layer 7. The exposed portion of the upper portion 12Eb forms the second pad portion P2 (planned contact region R) for electrical connection with the external member 50. Each of the lower portion 12Ea and the upper portion 12Eb has a three-layer structure similar to the lower portion 11a of the first electrode 11.

With the optical semiconductor element 1 of the second modification example as well, stable connection with the external member 50 using the solder 40 is possible and the light emission efficiency can be improved, as in the embodiment described above. In addition, since the second termination cell 3B does not have the optical layer 31 and the first semiconductor layer 32 and only has the second semiconductor layer 33, the configuration of the second termination cell 3B can be simplified.

The present disclosure is not limited to the embodiment and the modification examples described above. For example, the material and shape of each component are not limited to the materials and shapes described above, and various materials and shapes can be adopted. In the embodiment described above, the optical layer 31 has a multiple quantum well structure, but the optical layer 31 may be configured as a single layer. The material of the optical layer 31 is not limited to the example in the embodiment described above, and the optical layer 31 may be formed of a material containing at least one of InAsSb, AlInSb, and AlInAs. The optical layer 31 may be formed of a material containing Sb and In. The optical layer 31 may be formed of a material containing Sb. Even in these cases, the optical layer 31 can be configured as an active layer that generates light having a central wavelength of 3 μm or more and 10 μm or less. The optical layer 31 may be an active layer that generates light having a central wavelength of 3 μm or more and 8 μm or less, or may be an absorption layer having a maximum sensitivity wavelength of 3 μm or more and 8 μm or less. The wiring layer 4, the first electrode 11, and the second electrode 12 may be formed of a metal material other than those described above. The wiring layer 4 does not necessarily have to be formed in a layered shape.

In the embodiment described above, the second extending portion 4Bb of the second wiring layer 4B partially surrounds the four side portions 31a of the optical layer 31 of the second cell 3 Db, but the second extending portion 4Bb may surround the entire circumference of the optical layer 31. In other words, the second extending portion 4Bb may surround the entire four side portions 31a of the optical layer 31. For example, in the embodiment described above, the portions 43c and 43d of the second extending portion 4Bb may be connected to each other, and the second extending portion 4Bb may be formed in a rectangular ring shape when viewed from the Z direction. In this case, for example, by making the plane on which the first connection portion 4Aa of the first wiring layer 4A is arranged different from the plane on which the second extending portion 4Bb of the second wiring layer 4B is arranged, the first connection portion 4Aa and the second extending portion 4Bb are arranged so as to three-dimensionally cross (straddle) each other. In this case, the first connection portion 4Aa and the second extending portion 4Bb have portions overlapping each other when viewed from the Z direction.

In the embodiment described above, the second extending portion 4Bb extends in two different directions (In FIG. 2, the direction surrounding the optical layer 31 clockwise and the direction surrounding the optical layer 31 counterclockwise) starting from the intersection with the second portion 42 of the second connection portion 4Ba. However, when the second extending portion 4Bb partially surrounds the four side portions 31a of the optical layer 31 of the second cell 3 Db, the second extending portion 4Bb may extend in only one direction starting from the intersection with the second portion 42. Also in this case, the first connection portion 4Aa and the second extending portion 4Bb have portions overlapping each other when viewed from the Z direction. When the second extending portion 4Bb extends in two different directions starting from the intersection with the second portion 42, it is possible to shorten the length from the intersection with the second portion 42 to the distal end in the second extending portion 4Bb as compared with a case where the second extending portion 4Bb extends in only one direction. Therefore, since it is possible to increase the efficiency of carrier injection into the optical layer 31, it is possible to improve the light emission efficiency.

As another modification example, the optical semiconductor element 1 may be configured as a light receiving element. In this modification example, the optical semiconductor element 1 is configured as, for example, a photodiode. The optical layer 31 is an absorption layer that absorbs light, and has a maximum sensitivity wavelength of, for example, 3 μm or more and 10 μm or less. The optical layer 31 is configured in the same manner as the optical layer 31 of the embodiment described above, for example. In each cell 3, light incident through the substrate 2 is absorbed by the optical layer 31, and carriers are generated in the optical layer 31. The generated carriers are extracted through the first pad portion P1 (first electrode 11) and the second pad portion P2 (second electrode 12). Each cell 3 may be configured as a light detection cell capable of detecting light as in the embodiment described above, or the second termination cell 3B may be configured as a non-light detection cell that does not detect light as in the first and second modification examples.

According to this modification example, for the same reason as in the embodiment described above, stable connection with the external member 50 using the solder 40 is possible, and it is possible to improve the light reception efficiency. In addition, when the optical semiconductor element 1 is a light receiving element, if a plurality of cells 3 are electrically connected in series to each other, the resistance value of the optical semiconductor element 1 can be set to a value suitable for connection with an amplifier connected to the subsequent stage. That is, the optical semiconductor element 1 having a maximum sensitivity wavelength in the mid-infrared region has small resistance. The amplifier has a resistance value suitable for connection, and in order to increase the resistance to about the resistance value, the optical semiconductor element 1 adopts a structure in which a plurality of cells 3 are connected in series. If the resistance value of the optical semiconductor element 1 is too smaller than the target value, noise becomes large and accordingly, the signal is easily buried in the noise. In addition, when the optical semiconductor element 1 is a light receiving element, if a plurality of cells 3 are electrically connected in series to each other, thermal noise can be reduced. As a result, the total noise can be reduced. In a photodiode having sensitivity in the mid-infrared region, it is particularly important how the thermal noise can be reduced. More specifically, as the number of cells 3 connected in series increases, thermal noise is suppressed. The smaller the size of the optical semiconductor element 1, the more optical semiconductor elements 1 can be connected in series.

In the embodiment described above, the mesa portion 34 is formed in a trapezoidal shape in the cross section perpendicular to the main surface 2a of the substrate 2 (FIG. 4), but the mesa portion 34 may be formed in a rectangular shape in the cross section. In this case, the side surface of the mesa portion 34 may extend along the Z direction.

The material of each component is not limited to those described above. As an example, the substrate 2 may be formed of Si. The barrier layer of the first semiconductor layer 32 may be formed of (AlGa)_{0.20}In_{0.80}As, and the buffer layer and the contact layer of the first semiconductor layer 32 may be formed of In_{0.87}GaAs. The buffer layer of the second semiconductor layer 33 may be formed to have three layers consisting of GaAs, low temperature InAs, and In_{0.87}GaAs, respectively, the contact layer and the current diffusion layer of the second semiconductor layer 33 may be formed of In_{0.87}GaAs, and the barrier layer of the second semiconductor layer 33 may be formed of (AlGa)_{0.20}In_{0.80}AS. The first insulating layer 5 and the second insulating layer 6 may be formed of SiO₂. As another example, the substrate 2 may be formed of SI—InP. The barrier layer of the first semiconductor layer 32 may be formed of Al_{0.15}InAs, and the buffer layer and the contact layer of the first semiconductor layer 32 may be formed of InAs. The buffer layer of the second semiconductor layer 33 may be formed to have three layers formed of GaAs, low temperature InAs, and InAs, respectively, the contact layer and the current diffusion layer of the second semiconductor layer 33 may be formed of InAs, and the barrier layer of the second semiconductor layer 33 may be formed of Al_{0.15}InAs. The first insulating layer 5 and the second insulating layer 6 may be formed of SiN. As another example, the buffer layer of the second semiconductor layer 33 may be formed to have three layers formed of GaAs, InAs, and In_{0.87}GaAs.

The substrate 2 may be formed in a square shape, a circular shape, an elliptical shape, or the like when viewed from the Z direction. The optical layer 31, the first semiconductor layer 32, and the second semiconductor layer 33 may be formed in a square shape, a circular shape, an elliptical shape, or the like when viewed from the Z direction. The first electrode 11 and the second electrode 12 may be formed in a square shape, a circular shape, an elliptical shape, or the like when viewed from the Z direction. The first connection portion 4Aa of the first wiring layer 4A is not limited to the rectangular shape, and may be formed in any shape. The first connection portion 4Aa does not necessarily have to be arranged on the approximately entire surface 32a, and at least a part of the first connection portion 4Aa may be arranged on the surface 32a. When the substrate 2 is formed in a rectangular shape when viewed from the Z direction and the cell 3 (optical layer 31) is formed in a rectangular shape when viewed from the Z direction, the cell 3 can be efficiently arranged on the substrate 2.

The first termination cell 3A and the second termination cell 3B do not necessarily have to be arranged diagonally on the substrate 2 when viewed from the Z direction, and may be arranged at any position. The dummy pad cell 3C may not be provided.

The number of the plurality of cells 3 is not limited to the above example. For example, when the second termination cell 3B does not emit light, the plurality of cells 3 may include only the first termination cell 3A, the second termination cell 3B, and the cell 3E. In this case, the first termination cell 3A is electrically connected to the cell 3E. Alternatively, when the second termination cell 3B emits light, the plurality of cells 3 may include only the first termination cell 3A and the second termination cell 3B. In this case, the first termination cell 3A and the second termination cell 3B are electrically connected to each other.

The first cell in which the first electrode 11 is provided may not be the first termination cell 3A, and the first electrode 11 may be provided in the cell 3 other than the first termination cell 3A. That is, the first cell in which the first electrode 11 is provided does not necessarily have to be arranged at the end of the electrical series connection. Similarly, the second cell in which the second electrodes 12 and 12E are provided may not be the second termination cell 3B, and the second electrodes 12 and 12E may be provided in the cell 3 other than the second termination cell 3B. That is, the second cell in which the second electrodes 12 and 12E are provided does not necessarily have to be arranged at the end of the electrical series connection. The plurality of cells 3 may not be electrically connected in series, and may include portions connected in parallel, for example.

As described above, the third semiconductor layer of the second cell in which the second electrodes 12 and 12E are provided may be a p-type semiconductor layer (for example, the first semiconductor layer 32) or an n-type semiconductor layer (for example, the second semiconductor layer 33). The fourth semiconductor layer of the second cell in which the second electrodes 12 and 12E are provided may be a semiconductor layer having a different conductivity type from the third semiconductor layer, and may be a p-type semiconductor layer (for example, the first semiconductor layer 32) or an n-type semiconductor layer (for example, the second semiconductor layer 33).

The first electrode 11 may be formed by one metal layer. The second electrodes 12 and 12E may be formed by one metal layer. An insulating layer (the second insulating layer 6, the third insulating layer 7) may not be formed on the first electrode 11, and the first electrode 11 may be exposed to the outside. An insulating layer may not be formed on the second electrodes 12 and 12E, and the second electrodes 12 and 12E may be exposed to the outside. When an insulating layer is not formed, the planned contact region R is a region where the first electrode 11 or the second electrode 12 is in contact with the solder 40 (in a state in which the optical semiconductor element 1 is electrically connected to the external member 50).

In the second modification example, the top surface of the second termination cell 3B does not need to have the non-forming portion 3Ba in which the second electrode 12E is not formed. That is, the second electrode 12E may be formed on the entire top surface of the second termination cell 3B. In the second modification example, when viewed from the Z direction, the center CN1 of the planned contact region R of the second electrode 12E may be located on the center CN2 of the top surface of the second termination cell 3B, or may be located on the first electrode 11 side with respect to the center CN2. In the second modification example, the width W1 of a portion between the second termination cell 3B and the cell 3E in the wiring layer 4E may be equal to the width W2 of a portion between the cell 3E and the cell 3F in the wiring layer 4.

As a third modification example, the wiring layer 4 may be formed on the main surface 2a of the substrate 2 without providing the second termination cell 3B in the second modification example. In this case, a portion of the wiring layer 4 located within a region where the second termination cell 3B is formed can be used as the second electrode 12E. That is, the optical semiconductor element 1 may include the second electrode 12E arranged on the main surface 2a of the substrate 2 instead of the second termination cell 3B. Also in the third modification example, the second electrode 12E is electrically connected to the second semiconductor layer 33 of the adjacent cell 3E. The second electrode 12 may be arranged directly on the main surface 2a of the substrate 2, or may be arranged on the main surface 2a with an insulating layer interposed therebetween. That is, the second electrode 12 may be arranged on the main surface 2a with a layer other than the semiconductor layer interposed therebetween, and it is sufficient that no semiconductor layer is arranged between the second electrode 12 and the main surface 2a.

In the third modification example, the region on the substrate 2 where the second electrode 12E is arranged can be regarded as an arrangement region. The arrangement region corresponds to a region where the second termination cell 3B is formed in the second modification example. The arrangement region and the adjacent cell 3 are spaced apart from each other by the groove portion 37 formed in the substrate 2. In the third modification example, the arrangement region may have a non-forming portion in which the second electrode 12E is not formed, and the non-forming portion may be located in a region on the first electrode 11 side in the arrangement region when viewed from the Z direction. When viewed from the Z direction, the center CN1 of the planned contact region R of the second electrode 12E may be located on the side opposite to the first electrode 11 with respect to the center of the arrangement region.

That is, the optical semiconductor element 1 of the third modification example includes the substrate 2 and a plurality of cells 3 formed on the substrate 2, the plurality of cells 3 including the first termination cell 3A (first cell) and the cell 3E (second cell) electrically connected to each other. Each of the first termination cell 3A and the cell 3E includes the optical layer 31 that is an active layer that generates light, the first semiconductor layer 32 arranged on a side opposite to the substrate 2 with respect to the optical layer 31, and the second semiconductor layer 33 having a different conductivity type from the first semiconductor layer 32 and arranged on a side of the substrate 2 with respect to the optical layer 31. The first electrode 11 electrically connected to the first semiconductor layer 32 of the first termination cell 3A is arranged on the top surface of the first termination cell 3A. The second electrode 12E electrically connected to the second semiconductor layer 33 of the cell 3E is arranged on the substrate 2. Each of the first electrode 11 and the second electrode 12E has the planned contact region R with which the solder 40 comes into contact during electrical connection with the external member 50. When viewed from the Z direction (thickness direction of the substrate 2), the area of the second electrode 12E is smaller than the area of the first electrode 11 on the top surface of the first termination cell 3A. With the optical semiconductor element 1 of the modification example as well, for the reasons mentioned above, stable connection with the external member 50 using the solder 40 is possible and the light emission efficiency can be improved, as in the embodiment described above.

In the optical semiconductor element 1 of the third modification example, a plurality of adjacent cells 3 are spaced apart from each other by the groove portion 37 formed in the substrate 2, and the arrangement region on the substrate 2 where the second electrode 12E is arranged and the plurality of cells 3 adjacent to the arrangement region are spaced apart from each other by the groove portion 37 formed in the substrate 2. Therefore, the plurality of adjacent cells 3 can be spatially separated from each other by the groove portion 37, and the arrangement region where the second electrode 12E is arranged can be spatially separated from the plurality of cells 3 adjacent to the arrangement region by the groove portion 37.

In the optical semiconductor element 1 of the third modification example, the arrangement region has a non-forming portion in which the second electrode 12E is not formed, and the non-forming portion is located in a region on the first electrode 11 side in the arrangement region when viewed from the Z direction. Therefore, it is possible to suppress the occurrence of a short circuit between the first electrode 11 and the second electrode 12E.

In the optical semiconductor element 1 of the third modification example, when viewed from the Z direction (thickness direction of the substrate 2), the center CN1 of the planned contact region R of the second electrode 12E is located on the side opposite to the first electrode 11 with respect to the center of the arrangement region. Therefore, it is possible to suppress the occurrence of a short circuit between the first electrode 11 and the second electrode 12E.

In the optical semiconductor element 1 of the third modification example, the plurality of cells 3 include the cell 3F (third cell) having the optical layer 31, the first semiconductor layer 32, and the second semiconductor layer 33. The second electrode 12E is electrically connected to the second semiconductor layer 33 of the cell 3E (second cell) through the wiring layer 4E (first wiring layer). The first semiconductor layer 32 of the cell 3E is electrically connected to the second semiconductor layer 33 of the cell 3F through the wiring layer 4 (second wiring layer). The width W1 of a portion between the second electrode 12E and the cell 3E in the wiring layer 4E is larger than the width W2 of a portion between the cell 3E and the cell 3F in the wiring layer 4 that connects the cell 3E and the cell 3F to each other. The solder 40 diffuses into the wiring layer 4E through the second electrode 12E. However, since the width of the wiring layer 4E is large, it is possible to suppress the occurrence of wire breakage and the like in the wiring layer 4E even if the solder 40 diffuses into the wiring layer 4E to reduce the strength of the wiring layer 4E.

### REFERENCE SIGNS LIST

1: optical semiconductor element, 2: substrate, 3: cell, 3A: first termination cell (first cell), 3B: second termination cell (second cell), 3Ba: non-forming portion, 3D: cell (third cell, fourth cell, additional cell), 3E: cell (third cell, second cell), 3F: cell (fourth cell), 4: wiring layer, 4E: wiring layer (first wiring layer), 11: first electrode, 11a: lower portion (second layer), 11b: upper portion (first layer), 12, 12E: second electrode, 12a1, 12Ea: lower portion (second layer), 12a2, 12Eb: upper portion (first layer), 12E: second electrode, 31: optical layer, 32: first semiconductor layer (third semiconductor layer, fourth semiconductor layer), 33: second semiconductor layer (third semiconductor layer, fourth semiconductor layer), 40: solder, 50: external member, CN1, CN2: center, R: planned contact region, W1, W2: width.

1. An optical semiconductor element, comprising:
a substrate; and
a plurality of cells formed on the substrate, the plurality of cells including a first cell, a second cell, and a third cell that are electrically connected,
wherein each of the first cell and the third cell includes:
an optical layer that is an active layer that generates light or an absorption layer that absorbs light;
a first semiconductor layer arranged on a side opposite to the substrate with respect to of the optical layer; and
a second semiconductor layer having a different conductivity type from the first semiconductor layer and arranged on a side of the substrate with respect to the optical layer,
the second cell includes at least a third semiconductor layer arranged on the substrate,
a first electrode electrically connected to the first semiconductor layer of the first cell is arranged on a top surface of the first cell,
a second electrode electrically connected to the second semiconductor layer of the third cell is arranged on a top surface of the second cell,
each of the first electrode and the second electrode includes a planned contact region with which solder comes into contact during electrical connection with an external member, and
when viewed from a thickness direction of the substrate, an area of the second electrode on the top surface of the second cell is smaller than an area of the first electrode on the top surface of the first cell.

2. An optical semiconductor element, comprising:
a substrate having a light transmissivity; and
a plurality of cells formed on the substrate, the plurality of cells including a first cell and a second cell that are electrically connected,
wherein each of the first cell and the second cell includes:
an optical layer that is an active layer that generates light or an absorption layer that absorbs light;
a first semiconductor layer arranged on a side opposite to the substrate with respect to the optical layer; and
a second semiconductor layer having a different conductivity type from the first semiconductor layer and arranged on a side of the substrate with respect to the optical layer,
light generated in the optical layer is emitted through the substrate when the optical layer is the active layer, and light incident through the substrate is absorbed by the optical layer when the optical layer is the absorption layer,
a first electrode electrically connected to the first semiconductor layer of the first cell is arranged on a top surface of the first cell,
a second electrode electrically connected to the second semiconductor layer of the second cell is arranged on a top surface of the second cell,
each of the first electrode and the second electrode has a planned contact region with which solder comes into contact during electrical connection with an external member, and
when viewed from a thickness direction of the substrate, an area of the second electrode on the top surface of the second cell is smaller than an area of the first electrode on the top surface of the first cell.

3. The optical semiconductor element according to claim 2,
wherein each of the first electrode and the second electrode is opaque to light generated or absorbed in the optical layer.

4. The optical semiconductor element according to claim 1,
wherein the top surface of the second cell includes a non-forming portion in which the second electrode is not formed, and
the non-forming portion is located in a region on a side of the first electrode of the top surface of the second cell when viewed from the thickness direction of the substrate.

5. The optical semiconductor element according to claim 1,
wherein, when viewed from the thickness direction of the substrate, a center of the planned contact region of the second electrode is located on a side opposite to the first electrode with respect to a center of the top surface of the second cell.

6. The optical semiconductor element according to claim 1,
wherein the plurality of cells further include a fourth cell including the optical layer, the first semiconductor layer, and the second semiconductor layer,
the second electrode is electrically connected to the second semiconductor layer of the third cell through a first wiring layer,
the first semiconductor layer of the third cell is electrically connected to the second semiconductor layer of the fourth cell through a second wiring layer, and
a width of a portion between the second cell and the third cell in the first wiring layer is larger than a width of a portion between the third cell and the fourth cell in the second wiring layer.

7. The optical semiconductor element according to claim 1,
wherein the third semiconductor layer is arranged directly on the substrate, and the second electrode is arranged on the third semiconductor layer.

8. The optical semiconductor element according to claim 1,
wherein the second cell includes the optical layer, the third semiconductor layer arranged on the side opposite to the substrate with respect to the optical layer, a fourth semiconductor layer having a different conductivity type from the third semiconductor layer and arranged on the side of the substrate with respect to the optical layer, and an insulating layer arranged on the third semiconductor layer, and
the second electrode is arranged on the insulating layer.

9. The optical semiconductor element according to claim 2,
wherein the plurality of cells further include an additional cell including the optical layer, the first semiconductor layer, and the second semiconductor layer, and
the first semiconductor layer of the second cell is electrically connected to the second semiconductor layer of the additional cell through a wiring layer.

10. The optical semiconductor element according to claim 1,
wherein each of the first electrode and the second electrode includes a first layer and a second layer arranged on a side of the substrate with respect to the first layer.

11. The optical semiconductor element according to claim 10,
wherein each of the first layer and the second layer includes a layer consisting of Ti, a layer consisting of Pt, and a layer consisting of Au in this order from the side of the substrate.

12. The optical semiconductor element according to claim 1,
wherein each of the first electrode and the second electrode is formed of a material containing at least Au.

13. The optical semiconductor element according to claim 1,
wherein an insulating layer is formed on the first electrode and the second electrode except for the planned contact region.

14. The optical semiconductor element according to claim 1,
wherein each of the plurality of cells has a mesa structure including a side surface inclined with respect to the thickness direction of the substrate.

15. An optical semiconductor element, comprising:
a substrate; and
a plurality of cells formed on the substrate, the plurality of cells including a first cell and a second cell that are electrically connected,
wherein each of the first cell and the second cell includes:
an optical layer that is an active layer that generates light or an absorption layer that absorbs light;
a first semiconductor layer arranged on a side opposite to the substrate with respect to the optical layer; and
a second semiconductor layer having a different conductivity type from the first semiconductor layer and arranged on a side of the substrate with respect to the optical layer,
a first electrode electrically connected to the first semiconductor layer of the first cell is arranged on a top surface of the first cell,
a second electrode electrically connected to the second semiconductor layer of the second cell is arranged on the substrate,
each of the first electrode and the second electrode has a planned contact region with which solder comes into contact during electrical connection with an external member, and
when viewed from a thickness direction of the substrate, an area of the second electrode is smaller than an area of the first electrode on the top surface of the first cell.

16. The optical semiconductor element according to claim 15,
wherein the plurality of cells adjacent to each other are spaced apart from each other by a groove formed in the substrate, and
an arrangement region on the substrate where the second electrode is arranged and the plurality of cells adjacent to the arrangement region are spaced apart from each other by a groove portion formed in the substrate.

17. The optical semiconductor element according to claim 16,
wherein the arrangement region includes a non-forming portion in which the second electrode is not formed, and
the non-forming portion is located in a region on a side of the first electrode in the arrangement region when viewed from the thickness direction of the substrate.

18. The optical semiconductor element according to claim 16,
wherein, when viewed from the thickness direction of the substrate, a center of the planned contact region of the second electrode is located on a side opposite to the first electrode with respect to a center of the arrangement region.

19. The optical semiconductor element according to claim 16,
wherein the plurality of cells further include a third cell including the optical layer, the first semiconductor layer, and the second semiconductor layer,
the second electrode is electrically connected to the second semiconductor layer of the second cell through a first wiring layer,
the first semiconductor layer of the second cell is electrically connected to the second semiconductor layer of the third cell through a second wiring layer, and
a width of a portion between the second electrode and the second cell in the first wiring layer is larger than a width of a portion between the second cell and the third cell in the second wiring layer.

20. The optical semiconductor element according to claim 2,
wherein each of the first electrode and the second electrode includes a first layer and a second layer arranged on a side of the substrate with respect to the first layer.

21. The optical semiconductor element according to claim 20,
wherein each of the first layer and the second layer includes a layer consisting of Ti, a layer consisting of Pt, and a layer consisting of Au in this order from the side of the substrate.

22. The optical semiconductor element according to claim 2,
wherein an insulating layer is formed on the first electrode and the second electrode except for the planned contact region.

23. The optical semiconductor element according to claim 2,
wherein each of the plurality of cells has a mesa structure including a side surface inclined with respect to the thickness direction of the substrate.
